(19) United States
(12) Patent Application Publication
(10) Pub. No.: US 2010/0132759 A1
(43) Pub. Date: Jun. 3, 2010

(54) CELL ISOLATION ON PHOTOVOLTAIC MODULES FOR HOT SPOT REDUCTION

(76) Inventors: Renhe JIA, Berkley, CA (US); Dapeng Wang, Santa Clara, CA (US); Michel Frei, Palo Alto, CA (US); Tzay-Fa(Jeff) Su, San Jose, CA (US); David Tanner, San Jose, CA (US); Chris Eberspacher, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/483,948

(22) Filed: Jun. 12, 2009

(51) Int. Cl. H01L 31/042; H01L 21/304

(52) U.S. Cl. 136/244; 438/80; 257/E21.237

(57) ABSTRACT

Embodiments of the present invention provide methods for fabricating a solar cell on a substrate that have proportionally reduced current to minimize or reduce the likelihood of shading of a portion of the solar cell causing damage to the formed device. In one embodiment, a method for fabricating a series of solar cell arrays on a substrate includes providing a substrate having a TCO layer formed thereon, forming a first plurality of vertical scribing lines and a first plurality of horizontal scribing lines in the TCO layer, forming a film stack and a back metal layer on the scribed TCO layer, and forming a second plurality of the horizontal scribing lines in the film stack and the back metal layer, wherein the second plurality of horizontal scribing lines comprise pairs of scribing lines formed adjacent to each respective one of the first plurality of the horizontal scribing lines formed in the TCO layer.

### BACKGROUND

1. Field of the Invention

The present invention relates to methods for forming solar cell arrays on photovoltaic modules on a substrate, more particularly, for forming solar cell arrays on photovoltaic modules on a substrate with minimum hot spot effect.

2. Description of the Background Art

Photovoltaic (PV) arrays or solar arrays are devices which convert sunlight into direct current (DC) electrical power. Photovoltaic (PV) arrays or solar arrays are typically comprised by a plurality of photovoltaic cells, also known as solar cells. PV or solar cells typically have one or more p-i-n junctions. Each junction comprises two different regions within a semiconductor material where one side is denoted as the p-type region and the other as the n-type region. When the p-i-n junction of the PV cell is exposed to sunlight (consisting of energy from photons), the sunlight is directly converted to electricity through a PV effect. Each of the PV solar cells generate a specific amount of electric power and are typically formed in an array of series or parallel connected PV solar cells that deliver a desired amount of current and/or voltage. Typically, the arrays of PV solar cells are connected in series to form a PV module 101 that can then be connected with other PV modules to further increase the delivered power output of the array of PV modules when they are all connect to an external load. The PV modules 101, containing the series connect PV solar cells, may alternately be connected in parallel in order to increase the total current of the resulting array of PV modules.

FIG. 1 depicts a plain view of a multiplicity of formed PV solar cells, or solar cells 112A, connected into a solar array 112, which are all electrically connected and formed on a substrate 100. The multiplicity of solar cells 112A are electrically connected to the buss lines 114 that are each located at opposing ends of the solar array 112. A cross-buss 116 is then electrical connected to the buss line 114 to collect the current and voltage generated therefrom to a junction box 108. In order to form a desired number and patterns of cells on the substrate 100, a plurality of scribing process may be performed on the material layers formed on the substrate 100 to achieve cell-to-cell and cell-to-edge isolation. For example, the scribing process may be performed to form scribe lines P1ᵥ, P2ᵥ, and P3ᵥ in different material layers of the cells to form isolation groves on the substrate 100. FIG. 2 depicts a cross sectional view of the substrate 100 cutting along the cutaway line A-A′ of FIG. 1. It is noted that a P1 scribing process often refers to a scribing process performed in a transparent conductive oxide (TCO) layer 102 disposed on the substrate 100. A P2 scribing process often refers to a scribing process performed in a film stack 104 disposed on the TCO layer 102, and a P3 scribing process often refers to a scribing process performed in a back metal layer 106 disposed over the film stack 104. One will note that the scribe lines P1ᵥ and P2ᵥ, which are generally offset in a horizontal direction (x-direction in FIG. 1), are not shown in FIG. 1 for clarity. The scribe lines P1ᵥ and P2ᵥ are generally aligned parallel to the scribe line P3ᵥ and are positioned below the back metal layer 106 (FIG. 2). In the example depicted in FIGS. 1 and 2, a vertical P1 scribing process is performed to form an isolation line P1ᵥ in the TCO layer 102. The term “vertical”, as used herein to describe the orientation of the scribing lines, generally includes scribe lines that are aligned in a direction parallel to the Y-direction and perpendicular to the horizontal direction (X-direction), which are shown in FIGS. 1 and 3A. The formed X-Y plane is generally parallel to the surface 100A (FIG. 2) of the substrate 100 on which the material layers are formed. A vertical P2 scribing process is performed to form an isolation line P2ᵥ in the film stack 104 formed over the TCO layer 102. Furthermore, a vertical P3 scribing process is performed on the back metal layer 106 disposed over the film stack 104 to form the isolation line P3ᵥ. As shown in FIG. 2, each scribing line P1ᵥ, P2ᵥ, and P3ᵥ are consecutively and vertically (y-direction) formed in film layers during different stages of the solar cell formation process to form a series of solar cells 112A on the substrate 100.

However, a problem arises when individual solar cells 112A or portions of the individual solar cells 112A are not generating electricity, such as when some subset of solar cells are shaded. During operation, the current flowing through the solar cells 112A that are connected in series in the solar array 112 pass through each solar cell 112A. When one or more solar cells 112A are shaded, the current generated by the other unshaded cells in the solar array 112 needs to pass through the shaded cells as well. Due to the lack of generated current in the shaded cell(s), a reverse bias is created across the shaded solar cells, thereby resulting in heat being generated within the solar cells, which may create a “hot-spot” within the solar array 112. The magnitude of the reverse bias in a series connect solar array 112 is generally equivalent to the sum of number of volts generated by each of the light exposed solar cells. The created “hot spot” can damage the substrate 100 and/or deposited layers (e.g., reference numerals 102, 104, and 106) formed on the surface of the substrate. This phenomenon is often referred as reverse-bias degradation, breakdown, shading, or shadowing effect. In an extreme case, the formed “hot-spot” may destroy a photovoltaic cell and generate cracks in the substrate 100, and thus degrade the solar array, thereby resulting in scraping of the PV module 101 containing the solar array 112.

Additionally, it is typical that the films disposed on the substrate 100 (e.g., reference numerals 102, 104, and 106) may not have a uniform thickness across the substrate surface, leading to an uneven current distribution across the substrate 100 surface. Similarly, uneven current distribution may also result in current accumulation at certain spot of the solar cell arrays, thereby resulting in an undesired “hot-spot” effect or reverse-bias degradation.

Therefore, there is a need for a method for fabricating solar cell arrays that are less likely to have hot spot effects.

### SUMMARY OF THE INVENTION

The present invention provides a method for forming solar cell arrays on photovoltaic modules on a substrate to prevent hot spot effect. In one embodiment, a method for fabricating a series of solar cell arrays on a substrate includes providing a substrate having a TCO layer formed thereon, forming a plurality of first vertical scribing lines and a plurality of first horizontal scribing lines in the TCO layer, forming a film stack and a back metal layer on the scribed TCO layer, and forming a plurality of second horizontal scribing lines in the film stack and the back metal layer, wherein the plurality of second horizontal scribing lines comprise pairs of second horizontal scribing lines formed adjacent to each of the first horizontal scribing lines in the plurality of first horizontal scribing lines.

In another embodiment, a solar cell arrays formed on a substrate includes a substrate having a TCO layer, a film stack and a back metal layer consecutively formed thereon, a plurality of vertical scribing lines, wherein at least two vertical scribing lines are formed in the TCO layer, at least two vertical scribing lines are formed in the film stack and at least two vertical scribing lines are formed in the back metal layer, and each of the vertical scribing lines are aligned parallel to one another, a plurality of first horizontal scribing lines formed in the TCO layer that intersect with the at least two vertical scribing lines formed in the TCO layer, and a plurality of second horizontal scribing lines extending through at least a portion of the film stack and the back metal layer and positioned adjacent to each of the first horizontal scribing lines.

In yet another embodiment, a method for fabricating a series of solar cell arrays on a substrate includes forming a transparent conductive oxide layer on a surface of a substrate, forming a plurality of first vertical scribing lines in the transparent conductive oxide layer to form a patterned transparent conductive oxide layer, forming a film stack over the patterned transparent conductive oxide layer, forming a plurality of second vertical scribing lines in the film stack to form a patterned film stack, forming a back metal layer over the patterned film stack, forming a plurality of third vertical scribing lines in the back metal layer to form a patterned back metal layer, and forming a plurality of first horizontal scribing lines by removing a portion of the back metal layer and a portion of the film stack, wherein the first horizontal scribing lines are substantially perpendicular to the vertical scribing lines and are placed in a spaced apart relationship to each other to form at least two or more segments to proportionally reduce the current passing through each segment.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a plain view of a substrate having a multiplicity of solar cell arrays formed thereon of the prior art;

FIG. 2 depicts a cross sectional view of a portion of solar cell arrays formed on the substrate cutting along section line A-A′ of FIG. 1;

FIG. 3A depicts a plain view of a substrate having a multiplicity of solar cell arrays formed thereon in accordance with one embodiment of the present invention;

FIG. 3B depicts a enlarged view of an portion of the solar cell arrays formed on the substrate depicted in FIG. 3A;

FIG. 3C depicts a cross sectional view of a portion of solar cell arrays formed on the substrate cutting along section line B-B′ of FIG. 3A;

FIG. 3D depicts a cross sectional view of a portion of solar cell arrays formed on the substrate cutting along section line B-B′ of FIG. 3A in accordance with another embodiment of the present invention;

FIG. 3E depicts a cross sectional view of a portion of solar cell arrays formed on the substrate cutting along section line B-B′ of FIG. 3A in accordance with yet another embodiment of the present invention;

FIG. 3F depicts a enlarged view of an portion of the solar cell arrays formed on the substrate depicted in FIG. 3A;

FIG. 4A depicts a current flow path of solar cell arrays formed in accordance with one embodiment of the present invention;

FIG. 4B depicts a schematic drawing regarding the electric circuit of solar cell arrays formed in accordance with one embodiment of the present invention; and

FIG. 5 depicts a flow diagram of a process sequence for fabricating a series of solar cell arrays on a substrate in accordance with one embodiment of the present invention.

FIG. 6A depicts a schematic drawing illustrating an electric circuit of a conventional array solar array 112 illustrated in FIGS. 1 and 2;

FIG. 6B depicts a schematic drawing illustrating an electric circuit of a horizontally partitioned solar array illustrated in FIGS. 3A-3F;

FIG. 7 depicts a plain view of a substrate having a multiplicity of solar cell arrays formed thereon in accordance with another embodiment of the present invention;

FIG. 8A depicts a schematic drawing illustrating an electric circuit having a series of bypass diodes formed on a conventional solar cell arrays; and

FIG. 8B depicts a schematic drawing illustrating an electric circuit having a series of bypass diodes formed on solar cell arrays with horizontal partitions.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide methods for fabricating a series of solar cell arrays on a substrate to prevent the hot spot effect from damaging the formed solar cell device. In one embodiment, the series of solar cells formed on a substrate are scribed in a predetermined pattern so as to substantially eliminate current accumulation or overheating at various locations along the array of solar cells. In one example, current accumulation or overheating of regions within the solar cell arrays may be substantially eliminated by forming solar cells in a desired pattern that is configured to reduce the maximum possible current flowing through each solar cell in the formed solar cell array, therefore, reducing the maximum possible current flowing across any shaded portion of a formed solar cell array and preventing damage to the formed device.

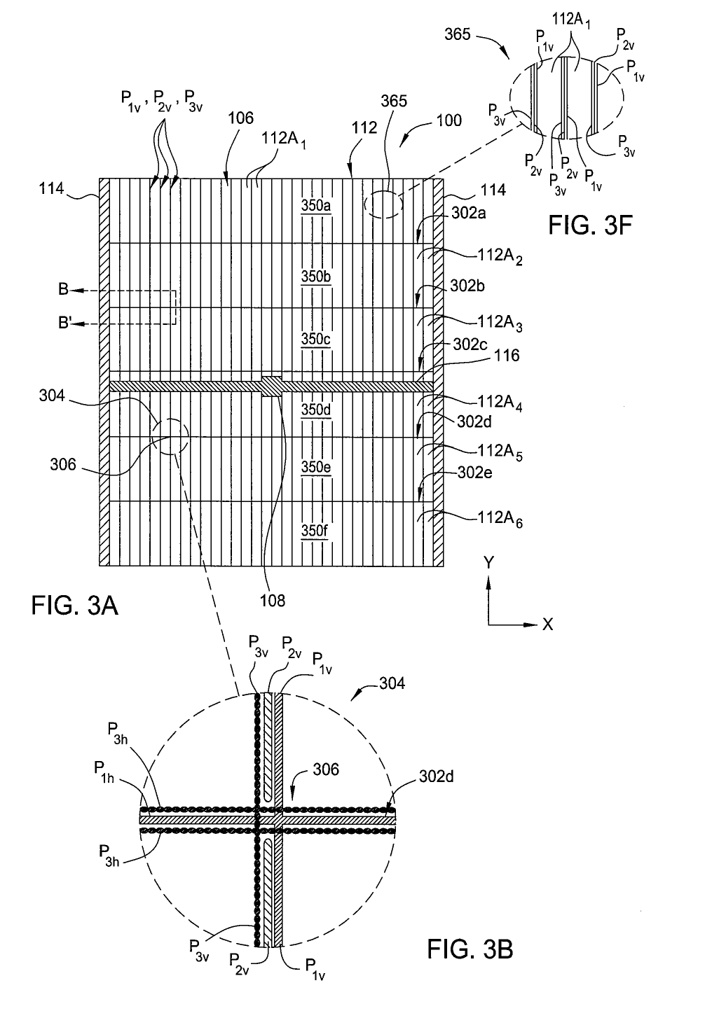

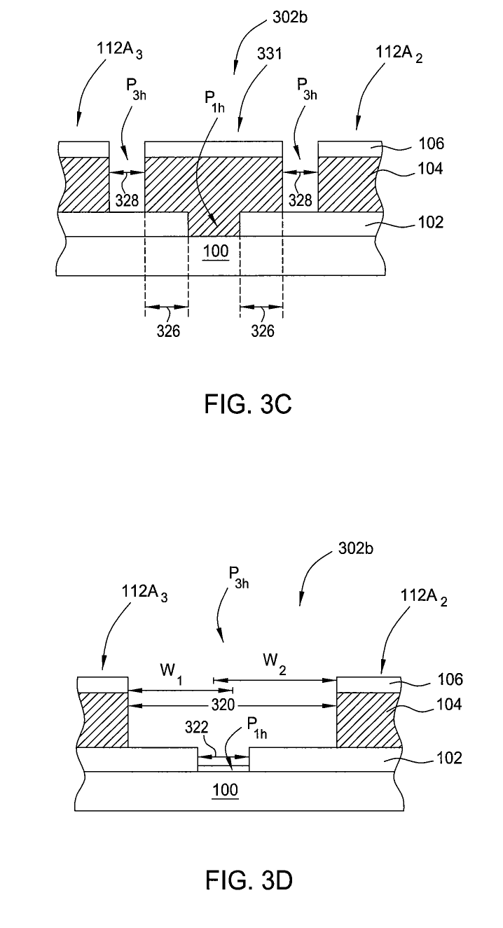

FIG. 3A depicts a plain view of a plurality of solar cell arrays formed on the substrate 100 having a desired scribing pattern configured to reduce current flow passing through certain spots/locations of the cells in accordance with one embodiment of the invention. The substrate 100 has different materials layers disposed thereon to form an array of solar cells on the substrate 100. As discussed above with referenced to FIG. 2, P1ᵥ line refers to a vertical scribing line (y-direction) formed on the TCO layer 102 disposed on the substrate 100. P2ᵥ line refers to a vertical scribing line (y-direction) formed on the film stack 104 disposed over the TCO layer 102, while the P3ᵥ line refers to a vertical scribing line (y-direction) formed within the back metal layer 106 which is disposed over the film stack 104. The TCO layer 102 may comprise, for example, a tin oxide (SnOₓ) layer, a zinc oxide (ZnO) layer, or an AZO layer, and the back metal layer 106 may comprise, for example, aluminum (Al), nickel (Ni), silver (Ag), Copper (Cu). In the embodiment depicted in FIG. 3A and 3F, a plurality of vertical P1, P2 and P3 scribing lines P1ᵥ, P2ᵥ, P3ᵥ are formed on the substrate 100 to scribe the devices into a desired pattern to form electrical connection line in between each cells. FIG. 3F is a close-up plan view of a region 365 of the solar array 112 illustrating one configuration of the scribing lines P1ᵥ, P2ᵥ, P3ᵥ formed in the various layers disposed on the substrate 100. The vertical scribing lines P1ᵥ, P2ᵥ, and P3ᵥ may be formed within the material layers disposed on the substrate 100 to isolate the solar cells 112A and/or regions within the formed solar cells 112A. Typically, having a large area and/or multiple arrays of solar cell devices formed in series may increase the likelihood of uneven current distribution across the solar array 112 when a portion of the solar array 112 are shaded or the film layers formed on the substrate have uneven film properties or thickness uniformity. Accordingly, horizontal partitions of solar cell devices are provided herein to isolate neighboring solar cells and divide the solar array 112 into multiple segments 350a-350f (FIG. 3A) of solar cells 112A₁- 112A₆ so as to proportionally reduce current passing through each individual solar cell 112A₁- 112A₆ contained in the segments 350a-350f, as compared to non-partitioned conventional solar cell arrays. In one embodiment, a plurality of horizontal partitions 302a-302e may be formed on the substrate 100 to equally space and isolate solar arrays 112 into multiple segments 350a-350f on the substrate 100. For example, as shown in FIG. 3A, each of the segments 350a-350f contain about 32 series connected solar cell 112A₁-112A₆, respectively, extending between the buss line 114.

In one embodiment, the number of the horizontal partitions 302a-302e may be varied as needed based on the size of the substrate 100, and maximum allowable current before the formed solar cells (e.g., reference numerals 112A₁-112A₆) to prevent damage to the substrate 100, and other design considerations. For example, when a substrate has a larger substrate dimension, a greater number of the horizontal partitions may be formed to partition the solar cells in the solar array 112 into greater number of different segments, and vise versa. In the exemplary embodiment depicted in FIG. 3A, five horizontal partitions 302a-302e are presented to partition the formed solar cells into six separated segments 350a-350f on the substrate 100 having a substrate dimension size about 1000 mm×1200 mm (a Generation 5 substrate size). As for a substrate having a size of about 2160 mm×2460 mm (a Generation 8.5 substrate size), up to 40 horizontal partitions may be utilized to divide the solar arrays 112 into different segments. In one embodiment, a solar array 112 having dimensions of about 1000 mm×1200 mm (a Generation 5 substrate size) has between about 1 and 20 horizontal partitions. In one embodiment, a solar array 112 having dimensions of about 2160 mm×2460 mm (a Generation 8.5 substrate size) has between about 1 and 80 horizontal partitions.

In one embodiment, each horizontal partition 302a-302e may include one or more scribing lines formed in different material layers disposed on the substrate 100 to space and isolate the solar arrays 112 into multiple segments 350a-350f. FIG. 3B depicts an enlarged view of a portion 304 of the substrate 100 having the horizontal partition 302d intersecting the vertical scribing lines P1ᵥ, P2ᵥ, P3ᵥ at the intersection point 306 formed between the segment 350d, 350e. In one embodiment, the horizontal partition 302d includes at least two horizontal P3 scribing lines P3ₕ (shown as water drop dotted line) sandwiching a horizontal P1 scribing line P1ₕ. Each horizontal P3 scribing line P3ₕ in each horizontal partition 302a-302e is spaced between about 5 μm and about 2000 μm, such as about 200 μm, away from the center horizontal P1 scribing line P1ₕ. In one embodiment, the horizontal P1 and P3 scribing lines P1ₕ, P3ₕ intersects the vertical scribing lines P1ᵥ and P3ᵥ (vertical P3ᵥ scribing line shown as water drop dotted line) but not the P2 scribing line P2ᵥ. The vertical P2 scribing line P2ᵥ is only formed in each segments 350a-350f defined between horizontal partitions 302a-302d without intersecting with the horizontal P1 and P3 scribing lines P1ₕ, P3ₕ. The vertical P2 scribing line P2ᵥ is formed only in each defined segment 350a-350f to help improve the electrical isolation between adjacent segments (e.g., segments 350d and 350e in FIG. 3B) by reducing the need to remove the often hard to remove back metal layer 106 disposed in the vertical scribe line P2ᵥ during the solar cell formation process. Alternatively, the vertical P2 scribing line P2ᵥ may intersect with the horizontal P1 and P3 scribing lines P1ₕ, P3ₕ as needed to simplify the vertical P2 scribing line P2ᵥ process. The stepped P2 process shown in FIG. 3B (non-continuous P2) is generally used to eliminate difficulties associated with removing materials from a given area if a continuous P2 scribing line P2ᵥ is used.

In one embodiment, the horizontal P1 and P3 scribing lines P1ₕ, P3ₕ may be formed across the entire width of the substrate 100 so as to substantially horizontally isolate the solar arrays 112 of solar cells (e.g., reference numerals 112A₁-112A₆) formed in each segment 350a-350f. As the solar arrays 112 are partitioned from the neighboring arrays, each solar array 112 formed in each segment 350a-350f is electrically isolated. As each segment 350a-350f is electrically isolated, the electrical current passing through each segment 350a-350f is proportionally reduced, as compared to the electrical current passing through all the solar cell arrays formed on the substrate 100 without partition. In the example depicted in FIG. 3A, as the solar arrays 112 are partitioned into six segments 350a-350f, the current flow through each segment 350a-350f is proportionally reduced to one sixth (⅙) of what would be present in a non-partitioned solar cell array. Therefore, the maximum possible current passing through each segment 350a-350f is reduced, thus reducing the amount of heat that can be generated when a portion of the substrate is shaded, thereby further reducing or eliminating the likelihood of the formed “hot-spots” damaging the formed device. Therefore, by adding an appropriate number of horizontal partitions and/or electrical isolation features to the solar arrays 112, the current flow in each segment 350a-350f formed on the substrate 100 can be reduced to prevent local current accumulation, reverse-bias degradation, and/or device breakdown created by the shading of a portion of a solar cell module.

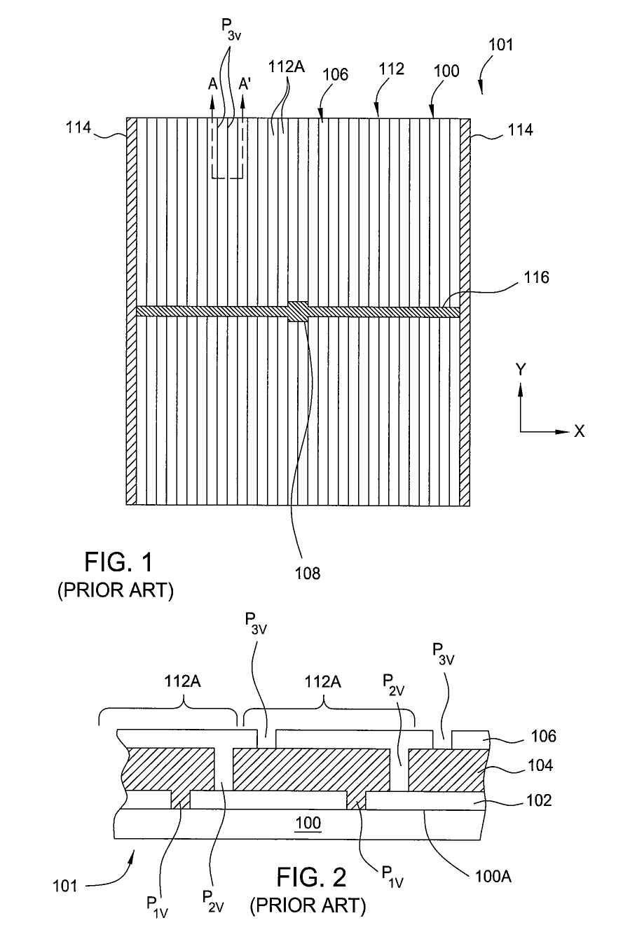

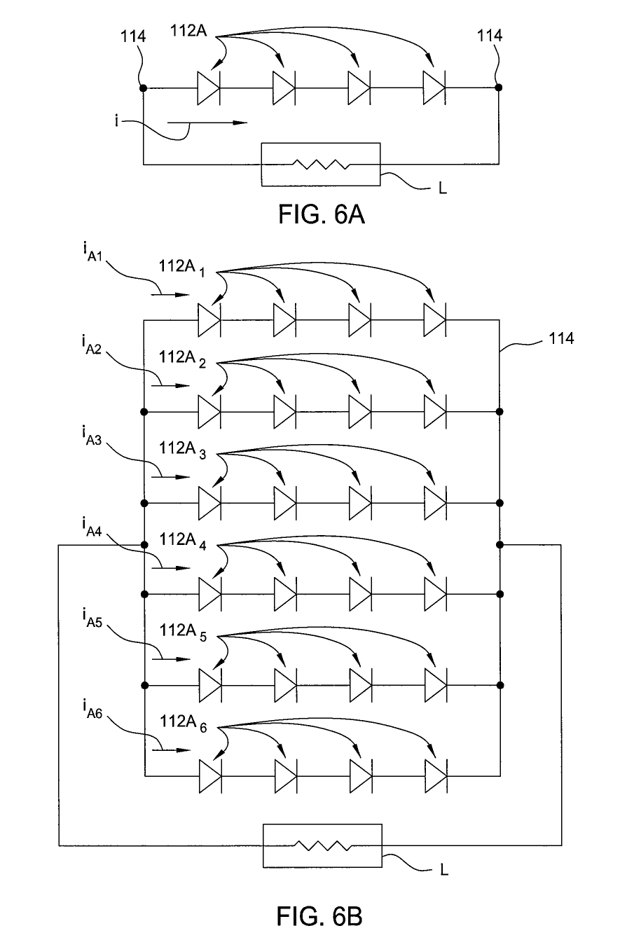

FIG. 6A is a schematic drawing illustrating an electric circuit of a conventional array solar array 112 illustrated in FIGS. 1 and 2. In this configuration, the generated current flow “i” passes from one buss line 114, through each of the series connected solar cells 112A and to the other buss line 114 when the solar cell is exposed to light and connected to an external load “L” (e.g., light bulb, electrical grid, battery). FIG. 6B is a schematic drawing illustrating an electric circuit of horizontally partitioned arrays of solar cells 112A₁-112A₆ illustrated in FIGS. 3A-3F. In this configuration, the generated current flow in each segment 350a-350f is split into parallel flowing currents “i_{A1}”-“i_{A6}” that passes from one buss line 114, through each of the series connected solar cells in their segments and to the other buss line 114 when the solar cells are exposed to light and connected to an external load “L” (e.g., light bulb, electrical grid, battery).

FIG. 3C is a cross sectional view taken along section line B-B′, shown in FIG. 3A, which illustrates the features of one embodiment of a horizontal partition line 302b that separates regions of two adjacent solar cells 112A₂ and 112A₃ which are formed on the substrate 100. As shown in FIG. 3C, the substrate 100 has a TCO layer 102, film stack 104, and a back metal layer 106. The TCO layer 102 serves as a first electrode, or top electrode that is disposed on the substrate 100. The back metal layer 106 may serve as a back electrode disposed on the substrate 100. The plurality of horizontal and vertical scribing lines or patterns may be formed on the substrate 100 to form a desired electrical connection and isolation to form a high efficiency solar array 112 and PV module. In one embodiment, horizontal and vertical scribing lines P1ᵥ, P2ᵥ, P3ᵥ, P1ₕ, P3ₕ are formed on the substrate 100 to electrically isolate the segments 350a-350f from each other by a laser ablation process, an etching process, or other suitable patterning process. In one embodiment, the TCO layer 102 may be zinc containing material, aluminum containing material, tin containing material, ITO containing material, alloys thereof, and any other suitable conductive materials. The back metal layer 106 may be metallic materials, such as copper (Cu), silver (Ag), gold (Au), tin (Sn), cobalt (Co), rhenium (Rh), nickel (Ni), zinc (Zn), lead (Pb), palladium (Pd), molybdenum (Mo), aluminum (Al) or nickel vanadium (NiV), among others.

The film stack 104 generally comprises a series of doped and intrinsic semiconductor layers that are used to form a single or multiple junction part of a solar cell device. In one embodiment, the film stack 104 includes a p-type silicon containing layer, a n-type silicon containing layer and an intrinsic type (i-type) silicon containing layer sandwiched between the p-type and n-type silicon containing layers. The silicon layers may be microcrystalline silicon based material, amorphous silicon based materials, or polysilicon based material. It is noted that multiple layers, more than three layers, may be formed in the silicon-containing film stack 104 for different process purposes. For example, multiple silicon based layers may be used in the silicon-containing film stack 104 to provide one or more, e.g., multiple, junctions to improve light conversion efficiency. In one exemplary embodiment, the silicon-containing film stack 104 includes a single solar cell junction having a p-type amorphous silicon layer, an i-type amorphous silicon layer, and an n-type amorphous silicon layer. In yet another exemplary embodiment, the silicon-containing film stack 104 includes a tandem junction having a top cell including a p-type amorphous silicon layer, an i-type amorphous silicon layer, and an n-type microcrystalline silicon layer, and a bottom cell including a p-type microcrystalline silicon layer, an i-type microcrystalline silicon layer and an n-type amorphous silicon layer. One suitable example of the silicon-containing film stack is disclosed in detail by U.S. application Ser. No. 11/624,677, filed Jan. 18, 2007 by Choi et al, titled “Multi-Junctions Solar Cells and Methods and Apparatus for Forming the Same”, (Attorney Docket no. APPM/11709), U.S. application Ser. No. 12/208,478, filed Sep. 11, 2008 by Sheng et al, titled “Microcrystalline Silicon Alloys for Thin Film and Wafer Based Solar Applications”, (Attorney Docket no. APPM/13551) and are herein incorporated by references.

Referring to FIG. 3C, the horizontal P3 scribing lines P3ₕ are formed on each side of the horizontal P1 scribing line P1ₕ to electrically isolate the two adjacent cells 112A₂ and 112A₃. As illustrated in FIG. 3C, in one embodiment, each horizontal P1 scribing line P1ₕ has two horizontal P3 scribing lines P3ₕ that are disposed on either side of the horizontal P1 scribing line P1ₕ. It is believed that by forming two horizontal P3 scribing lines P3ₕ on either side of the horizontal P1 scribing lines P1ₕ, the formed horizontal partition line (e.g., reference numeral 302b) will more effectively electrically isolate the adjacent solar cells by increasing the length of the current flow path and electrical resistance between the adjacent solar cells. The electrical resistance is increased since the current flow reverses through at least one diode formed in the structure. This configuration can be especially effective in cases where it is hard to reliably align the horizontal P1 scribing line P1ₕ and horizontal P3 scribing lines P3ₕ, which are performed at different times during the solar cell formation process and usually in different scribing tools. In some configurations, the horizontal P3 line P3ₕ cuts through both the back metal layer 106 and the film stack 104, while the vertical P3 line P3ᵥ (not shown in FIG. 3) will cut through the upper back metal layer 106, but may or may not cut through the film stack 104. In one embodiment, the width 328 of the horizontal P3 line P3ₕ is controlled at between about 5 μm and about 2000 μm, such as about 80 μm. The horizontal P3 line P3ₕ is spaced a distance 326 between about 5 μm and about 2000 μm, such as about 200 μm, from the horizontal P1 scribing line P1ₕ.

In one embodiment, two or more overlapping horizontal P3 scribing lines P3ₕ are used to form the horizontal partition line (e.g., reference numeral 302b), as shown in FIG. 3D. The overlapping horizontal P3 scribing line P3ₕ may result from the use of two horizontal P3 scribing lines P3ₕ, each having a scribing width W₁ and W₂, that overlap each other, thereby forming a single horizontal P3 scribing line P3ₕ having a opening width 320. The large overlapping P3 scribing line P3ₕ exposes the underneath horizontal P1 scribing line P1ₕ formed therebetween, providing desired electrical isolation horizontally on the solar arrays 112 formed on the substrate 100. In one embodiment, the horizontal P1 scribing line P1ₕ has an opening width 322 between about 5 μm and about 2000 μm. In one embodiment, the overlapping P3 scribing line P3ₕ has the opening width 320 between about 10 μm and about 4000 μm. This configuration can be especially effective in improving the electrical isolation between adjacent solar cells, since generally all of the material 331 (FIG. 3C) remaining between the adjacent solar cells can be removed during the material removal process performed during the horizontal P3 scribing line P3ₕ step.

Alternatively, one horizontal P3 scribing line P3ₕ, as shown in FIG. 3E, may be formed on the substrate, instead of two horizontal P3 scribing lines to reduce overall manufacture cost as well as maintaining good horizontal isolation between each segment 350a-350f. In one embodiment, the horizontal P3 scribing lines P3ₕ is aligned with the horizontal P1 scribing line P1ₕ to form a single channel 333 that passes through all of the layers disposed on the surface of the substrate 100. In one embodiment, the horizontal P3 scribing line P3ₕ has the opening width 324 between about 10 μm and about 4000 μm. In one embodiment, the depth of horizontal P3 scribe line P3ₕ is adjusted to remove a portion 330 of the substrate to assure complete removal of all of the deposited layers. In one embodiment, the depth 332 of the portion 330 of the substrate 100 is between about 0.01 and about 200 μm, such as about 50 μm. However, since the horizontal P1 scribing line P1ₕ may be between about 5 μm and about 2000 μm the ability to reliably place the horizontal P3 scribing line P3ₕ on top of each of the horizontal P1 scribing lines P1ₕ across the whole length of the substrate 100 (X-direction) can require the use of precisions automation components and alignment techniques. Also, optical inspection systems and control schemes that are able to accurately align the scribe lines are expensive and can greatly increase the system complexity.

In another embodiment, a single wide horizontal P3 scribing line P3ₕ and a single smaller horizontal P1 scribing line P1ₕ are used in combination to form the horizontal partition line. In this configuration, the single wide horizontal P3 scribing line P3ₕ may have a width equal to about W₁+W₂ shown in FIG. 3D. This configuration can be effective is cases where it is hard to reliably align a similarly sized horizontal P1 scribing line P1ₕ and horizontal P3 scribing lines P3ₕ, which are performed at different times during the solar cell formation process and usually in different scribing tools. This configuration can also be especially effective in electrically isolating adjacent solar cells, since generally all of the material 331 (FIG. 3C) remaining between the adjacent solar cells can be removed (FIG. 3D) during the material removal process performed during the single horizontal P3 scribing line P3ₕ material removal step

In yet another embodiment, a single P3 scribing line P3ₕ is used to cut through of the deposited material layers (e.g., the TCO layer, the film stack, and back metal layers) formed on the substrate 100, thus eliminating the need to perform the horizontal P1 scribing process. Therefore, no other horizontal scribing process need to be performed prior to performing the horizontal P3 scribing process. In this configuration, the scribing process needs to be effective in removing all of the deposited layers at once. For example, in cases where an optical laser is used to form the horizontal P3 scribing line P3ₕ a laser that delivers optical energy that is effective in removing the TCO layer 102, film stack 104 and back metal layer 106, such as an IR laser, is required. However, typically, in most solar cell fabrication processes it is not desirable for the laser scribing device used to perform the P3 vertical scribe to remove or damage the TCO layer 102, thus an additional laser having a different useable wavelength and power would be required to form the horizontal P3 scribing lines P3ₕ. The addition of a laser to form the horizontal P3 scribing lines P3ₕ will increase the solar cell process cost-of-ownership (CoO), increase the production line foot print and make the overall solar cell fabrication process more complex.

In one embodiment, the scribing process used to form the horizontal P1 and P3 scribing lines is a laser scribing process. The laser source may contain an infrared (IR) laser beam source, a Nd:vanadate (Nd:YVO₄) laser beam source, crystalline disk laser source, fiber-diode (fiber laser) or other suitable laser beam sources to ablate material from the substrate surface to form the horizontal P1 and P3 scribing lines that electrically isolate adjacent solar cells. In one embodiment, the laser beam source may emit a continuous or pulsed wave of radiation at a wavelength between about 1030 nm and about 1070 nm, such as about 1064 nm that is delivered from either side of the substrate 100. In one example, the laser beam source may emit a continuous or pulsed wave of radiation at a wavelength between about 200 nm and about 2000 nm, such as about 1064 nm that is delivered from either side of the substrate 100. The laser source efficiently removes the materials from the substrate 100 without damage adjacent layers disposed therearound. In one embodiment, the vertical P1 scribing process and horizontal P1 scribing process uses a 1064 nm wavelength pulsed laser to pattern the material disposed on the substrate 100, while the vertical P2 scribing process, vertical P3 scribing process and horizontal P3 scribing process each use a 532 nm wavelength pulsed laser to ablate desired regions of the deposited layers. The use of a 532 nm wavelength laser in the vertical P2, vertical P3 and horizontal P3 scribing processes has been found to be useful in preventing damage to the TCO layer. Alternatively, the laser source and/or laser scribing tool utilized to perform the vertical or horizontal P1, P2 or P3 process in each different layer may be configured the same as needed. Alternatively, a water jet cutting tool, a mechanical polishing tool, a diamond scribe tool, a diamond impregnated belt, grit blasting or a grinding wheel may also be used to mechanically grind, ablate, and isolate the various segments on the substrate 100 of the solar cells arrays as needed. In some cases, a dry or wet etching process may be used to form the horizontal P3 scribing line P3ₕ.

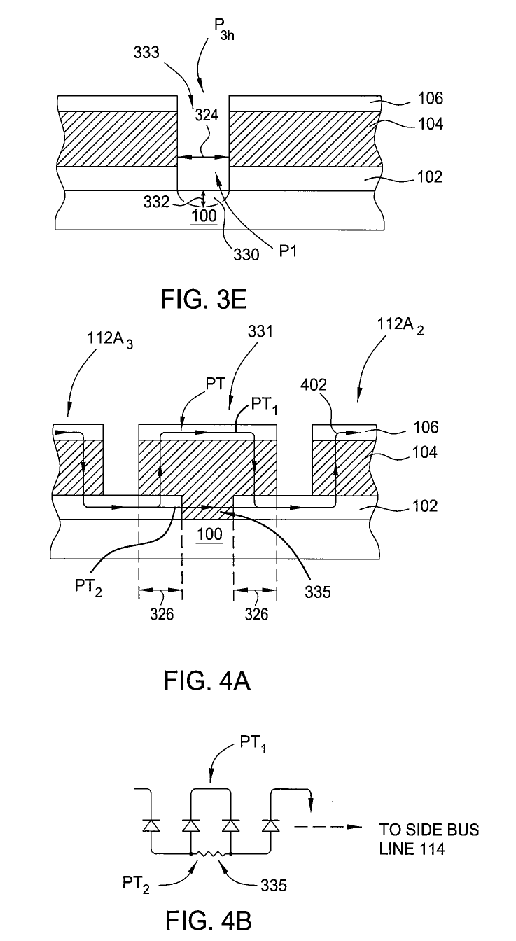

FIG. 4A depicts a current flow path “PT” delivered through the material 331 formed using the steps described above in conjunction with FIG. 3C. In general, the current flow path “PT” is created between a pair of adjacent solar cells, such as solar cells 112A₂-112A₃, when the potential in the adjacent cells disposed on either side of the horizontal partition 302b is high enough to cause current 402 to flow through the scribed region. FIG. 4B is a schematic drawing illustrating an electric circuit formed when creating a horizontal partition similar to one described above in conjunction with FIG. 3C and shown in FIG. 4A. In general, the current flow path “PT” includes the flow of current 402 through at least one forward and reversed biased p-i-n junction (e.g., schematically shown as a diode) created by the deposited layers that form the p-i-n junction in the solar cell device. In general, it is desirable to assure that the horizontal P1 scribing line P1ₕ is wide enough to prevent the bulk of the current flowing through the resistive path PT₂ versus resistive path PT₁. In one embodiment, the horizontal P1 scribing line P1ₕ has an opening width 335 of at least about 5 μm.

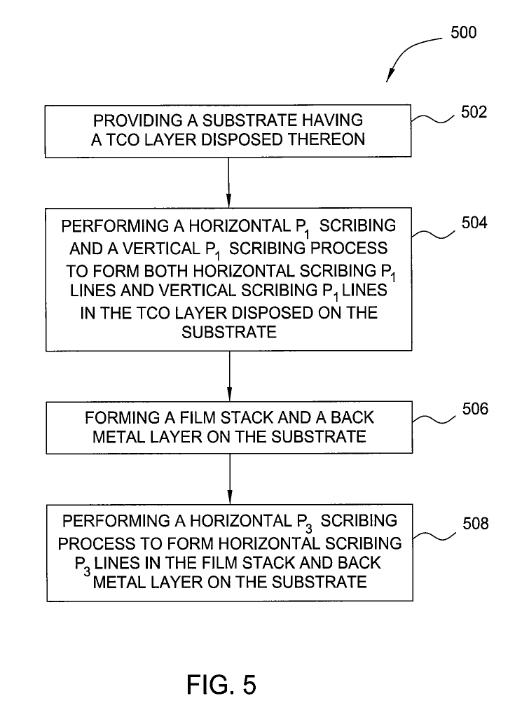

FIG. 5 is a process flow diagram illustrating one embodiment of a process sequence 500 that is used to form the horizontal partition 302a-302e on the substrate 100. The process 500 starts at step 502 by providing the substrate 100 having a TCO layer, such as the TCO layer 102 depicted in FIGS. 2 and 3B-3E. The TCO layer 102 may be formed on the substrate 100 by a PVD process, a CVD process, a coating process, or any other suitable process conventionally available. As noted above, the TCO layer 102 may be zinc containing material, aluminum containing material, tin containing material, ITO containing material, alloys thereof, and any other suitable conductive materials.

At step 504, a scribing process is performed on the TCO layer 102 to form desired partitions, isolations and patterns on the substrate 100. In this particular step, at least one vertical P1 scribing process and at least one horizontal P1 scribing process is performed on the TCO layer 102 to form a desired isolation groove pattern in the deposited TCO layer 102. For example, as shown in FIGS. 3A and 3B, a plurality of P1ᵥ scribing lines and P1ₕ scribing lines are formed on the TCO layer 102 to scribe the TCO layer 102 into a plurality of rectangular and/or square isolated arrays. In one embodiment, there may be between about 20 and about 200 vertical P1 scribing lines P1ᵥ for a substrate having a substrate size between about 1000 mm×1200 mm (a Generation 5 substrate size). The horizontal P1 scribing lines P1ₕ may be between about 1 scribing horizontal lines to about 50 scribing horizontal lines, such as about 5 scribing horizontal lines. In one embodiment, there may be between about 40 and about 400 vertical P1 scribing lines P1ᵥ for a substrate having a substrate size between about 2160 mm×2460 mm (a Generation 8.5 substrate size). The horizontal P1 scribing lines P1ₕ for such substrate may be between about 1 scribing horizontal lines to about 80 scribing horizontal lines, such as about 40 scribing horizontal lines.

At step 506, after the vertical P1 scribing lines P1ᵥ and horizontal P1 scribing lines P1ₕ are formed on the TCO layer 102, the film stack 104 is formed over the patterned TCO layer 102, filling the isolation grooves defined by the vertical and horizontal P1 scribing lines P1ᵥ, P1ₕ, as shown in FIGS. 2 and 3C. It is noted that FIG. 2 and FIG. 3C, respectively, depicts horizontal and vertical cross sectional views of the solar cell arrays formed on the substrate 100, as explained above. After deposition of the film stack 104, the back metal layer 106 is then disposed over the film stack 104. Prior to the deposition of the back metal layer 106, a vertical P2 scribing process may be performed to form P2 scribing lines P2, in the film stack 104, as shown in FIGS. 2 and 3B. In the embodiment depicted in FIG. 3B, the vertical P2 scribing line P2, is formed substantially parallel to the vertical P1 scribing line P1ᵥ and does not intersect with the underlying horizontal P1 scribing line P1ₕ. Instead, the vertical P2 scribing lines P2ᵥ skip the underlying horizontal P1 scribing line P1ₕ and only are formed within the segments 350a-350f defined between the horizontal P1 scribing lines P1ₕ. After the vertical P2 scribing process, the back metal layer 106 may be formed over the film stack 104. In one embodiment, the back metal layer 106 may be deposited to fill in the isolation scribing lines P2, defined in the film stack 104, as shown in the horizontal cross sectional view of FIG. 2. It is noted that, in one embodiment, no horizontal P2 scribing process is required to be formed in the film stack 104.

At step 508, after deposition of the back metal layer 106, a horizontal P3 scribing process is performed to form horizontal P3 scribing lines P3ₕ on the substrate 100, as shown in FIG. 3B. As discussed above, the horizontal P3 scribing lines P3ₕ are formed at each side of the horizontal P1 scribing lines P1ₕ. The horizontal P3 scribing lines P3ₕ scribes both the back metal layer 106 and the film stack 104 disposed on the substrate 100, as shown in FIG. 3C. As discussed above, variations of the scribing line width and the scribing process performed to form the horizontal P3 scribing lines P3ₕ would result in different embodiments of the scribing isolations, as further shown in FIGS. 3D-3E.

Prior to or after formation of the horizontal P3 scribing lines P3ₕ, the vertical P3 scribing process may also be performed to form vertical P3 scribing lines P3ᵥ in the back metal layer 106, as shown in FIG. 2 and FIG. 3B. It is noted that the vertical P3 scribing lines P3ᵥ are formed substantially in parallel with the vertical P2 and P1 scribing lines P2ᵥ, P1ᵥ and intersecting with the horizontal P1 and/or P3 scribing lines P1ₕ, P3ₕ.

The vertical and/or horizontal scribing lines formed in the different layers disposed on the substrate 100 are thus configured, oriented, aligned and positioned to provide desirable electrical isolation in various regions of the formed solar array 112. By carefully configuring, aligning, orienting and positioning the vertical and/or horizontal scribing lines, the electrical current passing through each defined and isolated segments 350a-350f will be proportionally reduced, thereby effectively reducing the possibility of damaging the substrate 100 or material layers formed thereon due to the generated heat created by the partial shading of the solar cell device. Accordingly, the likelihood of hot-spot effect occurrence can be effectively minimized or eliminated all together.

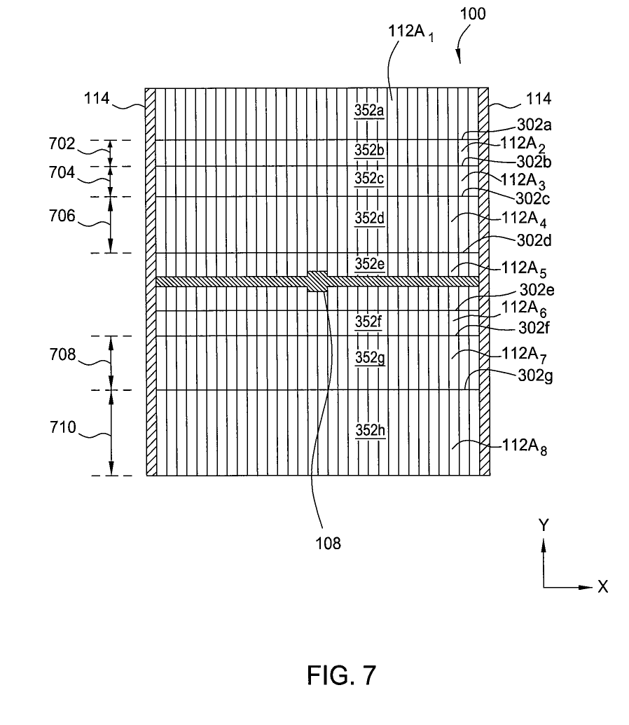

FIG. 7 depicts a plain view of a plurality of arrays of solar cells 112A₁-112A₈ formed on the substrate 100 having a desired scribing pattern configured to reduce current flow passing through certain spots/locations of the cells in accordance with another embodiment of the invention. Similar to the embodiment depicted in FIG. 3A, a plurality of horizontal partitions 302a-302g (7 partition lines are shown) may be formed on the substrate 100 to isolate neighboring solar cells into multiple segments 352a-352h of solar cells 112A₁-112A₈. The horizontal partitions 302a-302g (y-direction) are configured to be unevenly and unequally spaced across the substrate 100 to form the arrays of solar cells 112A₁-112A₈. As the film profile and thickness formed across the substrate 100 may vary, current accumulation at different locations in each of the arrays of solar cells 112A₁-112A₈ may also vary. For example, at a location where the material layers deposited thereon has a higher thickness, the current accumulated will be typically higher. Therefore, in order to reduce current accumulation and evenly distribute the generated current passing through in each partitioned segments 352a-352h, the distance 702, 704, 706, 708, 710 of each horizontal partition 302a-302g formed on the substrate 100 may be spaced and positioned in accordance with different film profiles or thickness formed at different locations of the substrate 100. Also, in some configurations it is desirable to vary the spacing of the horizontal partitions 302a-302g to compensate for the variation in temperature across the substrate 100 when the formed solar cell device is placed into use. Temperature variation across the substrate 100 during the generation of current by the solar cell device can be due to presence of heat sinks and/or regions that generate a higher amount of heat found on or within the formed solar cell device. Therefore, by adjusting the spacing between the horizontal partitions, the amount of heat generated (i.e., related to current flow) and operating temperature of each segment and/or each region of the solar cell can be controlled and optimized. In one embodiment, the spacing between adjacent horizontal partitions is not constant (e.g., segment width is not uniform) to compensate for variations in film properties or solar cell configurational differences. In yet another embodiment, the spacing between adjacent horizontal partitions and the spacing between adjacent vertical scribe lines may each be varied to compensate for variations in film properties or solar cell configurational differences.

In one embodiment, the uneven spaced distribution of the partitions may assist maintaining substantially similar current flow passing through each unit area partitioned in each segments 352a-352h. In one example, when an area of the substrate 100 has material layers that have a higher total film thickness versus other areas of the substrate 100, the density of the partitions formed in that area can be made higher to compensate for the differing amount current generated therein. For example, in the embodiment depicted in FIG. 7, in the segments 352b, 352c defined by the partitions 302a-302c having a higher material layer film thickness disposed thereon, and thus the distances 702, 704 defined between the partitions 302a-302c is configured to be shorter (e.g., high density of partition lines), as compared to other distances 708, 710 defined between the partitions 302f-302g. Accordingly, the segment 352b, 352c defined by the partitions 302b, 302c are narrower than the other segments 325d, 352e, 352h.

In contrast, when an area of the substrate 100 has material layers disposed thereon with lower film total thickness, the density of the partitions formed in that area can be relatively larger. A lower total film thickness translates to a large electrical field and as a result, a smaller breakdown voltage. For example, in the segments 352g, 352h defined by partitions 302f-302g having a lower material layer film thickness disposed thereon, the distance 708, 710 defined by the partitions 302f-302g is configured to be narrower, as compared to the distance between 302a-302c. Therefore, the segment 352g, 352h defined by the partitions 302f, 302g may be narrower, as compared to the other segment 325b, 352c, 352f. In one example, such as for use with a tandem junction solar cell, when the material layers disposed on the substrate 100 having a total thickness greater than 0.5 μm, the distance defined by each partition is configured to be about 220 mm. In another example, such as for use with a single junction solar cell, when the material layers disposed on the substrate 100 having a total thickness between about 0.01 and about 0.5 μm, the distance defined by each partition is configured to be about 120 μmm. It is noted that the number of the partitions, distance between each partitions may be varied in accordance with different film profile, film thickness, substrate dimension, and material characteristics and the like.

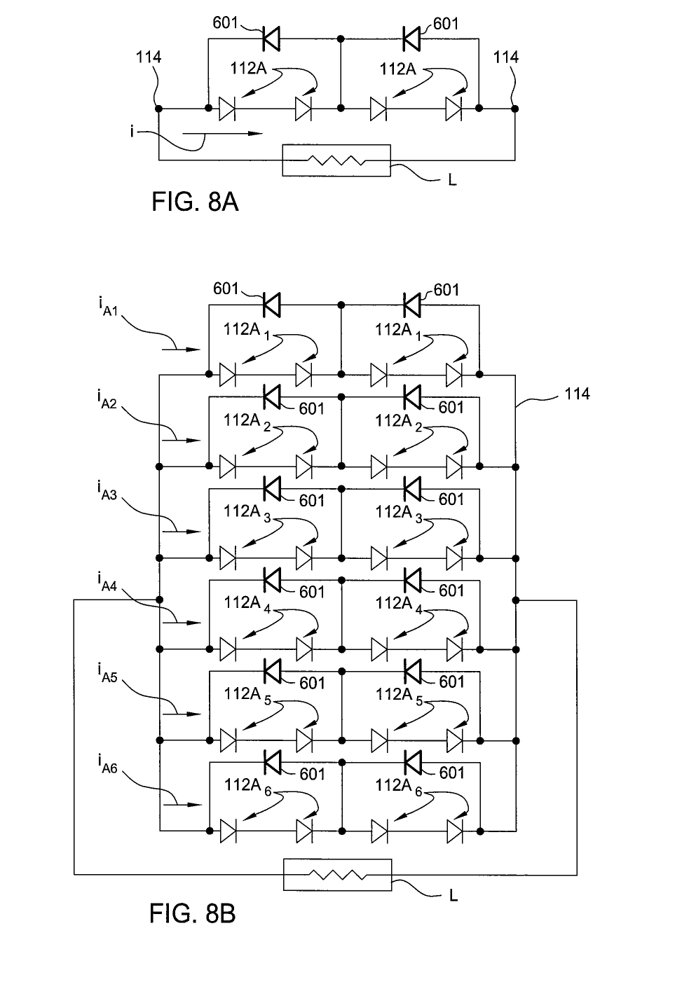

FIG. 8A is a schematic drawing illustrating an electric circuit having a series of bypass diodes 601 electrically connected to the solar cell arrays depicted in FIG. 6A. In order to reduce the chance that a solar cell device will be damaged by the “hot spot” effect, one or more bypass diodes may be used to protect the individual solar cells in the solar cell arrays. The bypass diode 601, as shown in FIG. 8A, may be disposed in parallel with the solar cells 112A. The bypass diode 601 allows the current from the solar cells 112A to flow through the external bypass diode 601 rather than reverse biasing each solar shaded solar cell, thus limiting the potential of the reverse bias voltage and preventing the solar cell from being damaged by the hot spot effect. In one embodiment, a bypass diode 601 may be disposed across any number solar cells in a solar array 112 to prevent hot spot effect. One bypass diode 601 may be installed for each solar cell disposed in the solar array 112. Alternatively, the bypass diode 601 may be installed across groups of solar cells 112A as needed. In one example, a bypass diode 601 is connected across N solar cells, where is an integer, such as N=1, 2, 3, 4, 5, 10, 20, 50 . . . or N_{T}-1, where N_{T} is the total number of solar cells in the array.

FIG. 8B is a schematic drawing illustrating one embodiment of an electric circuit having a series of bypass diodes 601 electrically connected to the horizontally partitioned arrays of solar cells 112A₁-112A₆ depicted in FIG. 6B. As the solar cells are horizontally partitioned into arrays of solar cells 112A₁-112A₆, bypass diodes 601 can be connected in parallel to any desirable number of horizontally partitioned solar cells 112A₁-112A₆ in each partitioned segment. As discussed above, the bypass diode 601 can effectively avoid excess reverse bias voltage accumulated on solar cell arrays due to partial shading of some of the solar cells, thereby preventing damage to the solar cell(s) due to the hot spot effect. In one embodiment, a bypass diode 601 may be connected across multiple solar cells 112A₁-112A₆ in each segment to prevent regions of the solar cell device from being damaged. While FIGS. 8A and 8B illustrate a bypass diode 601 connected every two horizontally partitioned solar cells 112A₁-112A₆, this configuration is not intended to be limiting. In one embodiment, the a bypass diode 601 is connected across N solar cells in each horizontally partitioned array of solar cells, where N is an integer, such as N=1, 2, 3, 4, 5, 10, 20, 50 . . . or N_{T}-1, where N_{T} is the total number of solar cells in each horizontally partitioned array of solar cells.

Thus, improved methods for fabricating a series of solar cell arrays on a substrate are provided. The method advantageously reduces the likelihood of overheating certain regions of the substrate by segmenting and/or isolating regions of the solar arrays from one another. By proper isolation of the solar cell arrays, the hot spot effect can be effectively eliminated, thereby reducing manufacture cost and increasing the lifetime of the PV module.

While the foregoing is directed to embodiments of the present invention, other and further embodiments of the invention may be devised without departing from the basic scope thereof, and the scope thereof is determined by the claims that follow.

1. A method for fabricating a series of solar cell arrays on a substrate comprising:
forming a plurality of first vertical scribing lines and a plurality of first horizontal scribing lines in a TCO layer disposed on a substrate;
forming a film stack and a back metal layer on the scribed TCO layer; and
forming a pair of second horizontal scribing lines in the film stack and the back metal layer, wherein the pair of second horizontal scribing lines sandwich one of the first horizontal scribing lines formed in the TCO layer.

2. The method of claim 1, wherein the pair of second horizontal scribing lines comprise a first scribe line laterally spaced from a first side of the first horizontal scribing line sandwiched by the pair and a second scribe line laterally spaced from a second side of the first horizontal scribbling line sandwiched by the pair.

3. The method of claim 2, wherein the pair of second horizontal scribing lines comprise the first scribe line at least partially overlapping the first horizontal scribing line sandwiched by the pair and the second scribe line at least partially overlapping the first horizontal scribing line sandwiched by the pair.

4. The method of claim 3, wherein the first and second scribe lines have a width between about 5 μm and about 2000 μm.

5. The method of claim 1, further comprising:
forming a plurality of second vertical scribing lines in the film stack and the back metal layer, wherein the plurality of second vertical scribing lines and the pair of horizontal scribing lines are formed by electromagnetic radiation having the same wavelength.

6. The method of claim 1, wherein the plurality pair of second horizontal scribing lines are aligned with the plurality of first horizontal scribing lines formed in the TCO layer.

7. The method of claim 6, wherein the first horizontal scribing lines and the pair of second horizontal scribing lines each have a width between about 5 μm and about 2000 μm.

8. The method of claim 1, wherein the first horizontal scribing lines are formed by electromagnetic radiation having a first wavelength and the pair of second horizontal scribing lines are formed by electromagnetic radiation having a second wavelength which is different than the first wavelength of electromagnetic radiation.

9. The method of claim 8, wherein the first wavelength is about 1064 nm and the second wavelength of electromagnetic radiation is about 532 nm.

10. The method of claim 1, wherein the first horizontal scribing lines and the pair of second horizontal scribing lines are formed by a water jet cutting tool, a mechanical polishing tool, a diamond scribe tool, a diamond impregnated belt, grit blasting or a grinding wheel.

11. The method of claim 1, wherein forming the pair of second horizontal scribing lines in the film stack and the back metal layer further comprises:
forming a plurality of third vertical scribing lines in the film stack prior to forming the pair of the second horizontal scribing lines in the film stack and the back metal layer, wherein the plurality of third vertical scribing lines are aligned parallel to the plurality of first vertical scribing lines.

12. The method of claim 11, wherein the plurality of third vertical scribing lines does not intersect the plurality of first horizontal scribing lines.

13. The method of claim 1, wherein forming the pair of second horizontal scribing lines in the film stack and the back metal layer further comprises:
forming scribing lines in the back metal layer that are aligned parallel with the plurality of first vertical scribing lines formed in the TCO layer.

14-20. (canceled)

21. A method for fabricating a solar cell, comprising:
forming a plurality of first vertical scribing lines in the a transparent conductive oxide layer disposed on a surface of a substrate to form a patterned transparent conductive oxide layer;
forming a film stack over the patterned transparent conductive oxide layer;
forming a plurality of second vertical scribing lines in the film stack to pattern the film stack;
forming a back metal layer over the patterned film stack;
forming a plurality of third vertical scribing lines in the back metal layer to form a patterned back metal layer; and
forming a plurality of first horizontal scribing lines by removing a portion of the back metal layer and a portion of the film stack from the substrate, wherein the first horizontal scribing lines are substantially perpendicular to the first vertical scribing lines and are placed in a spaced apart relationship to each other to form at least two or more segments to proportionally reduce the current passing through each segment.

22. The method of claim 21, further comprising:
forming a plurality of second horizontal scribing lines by removing a portion of the transparent conductive oxide layer before the film stack is deposited over the patterned transparent conductive oxide layer, wherein the second horizontal scribing lines are substantially perpendicular to the first vertical scribing lines, and at least one first horizontal scribing line is disposed on either side of a second horizontal scribing line.

23. The method of claim 21, further comprising:
forming a plurality of second horizontal scribing lines by removing a portion of the transparent conductive oxide layer before the film stack is deposited over the patterned transparent conductive oxide layer, wherein the second horizontal scribing lines are substantially perpendicular to the first vertical scribing lines, and
the forming of the plurality of the first horizontal scribing lines further comprises removing a portion of the back metal layer and a portion of the film stack from the substrate so that the film stack deposited within the second horizontal scribing lines is substantially removed.

24. The method of claim 21, further comprising:
forming a plurality of second horizontal scribing lines by removing a portion of the transparent conductive oxide layer before the film stack is deposited over the patterned transparent conductive oxide layer, wherein the second horizontal scribing lines are substantially perpendicular to the vertical scribing lines, and
wherein forming the plurality of first horizontal scribing lines comprises forming a pair of horizontal scribing lines in the film stack and the back metal layer so that one horizontal scribing line is disposed on either side of the second horizontal scribing lines.

25. The method of claim 24, wherein each of the plurality of first horizontal scribing lines is disposed between about 5 μm and about 2000 μm from the plurality of second horizontal scribing lines.
